(19) United States
(12) Patent Application Publication
(10) Pub. No.: US 2006/0213642 A1
(43) Pub. Date: Sep. 28, 2006

(54) Method of combining heat sink and heat conductor and combination assembly of the same

(75) Inventor: Yaw-Huey Lai, Taipei County (TW)

Correspondence Address: BACON & THOMAS, PLLC, 625 SLATERS LANE, FOURTH FLOOR, ALEXANDRIA, VA, 22314, US

(73) Assignee: TAI-SOL ELECTRONCS CO., LTD., TAIPEI CITY (TW)

(21) Appl. No.: 11/135,357

(22) Filed: May 24, 2005

(30) Foreign Application Priority Data
Mar. 25, 2005 (TW) 94109491

(51) Int. Cl. H05K 7/20

(52) U.S. Cl. 165/80.3; 361/704

(57) ABSTRACT

A method of combining a heat sink and a heat conductor and the combination assembly of the same includes the steps of preparing a heat sink and a heat conductor, wherein the heat sink includes a sleeve, a plurality of cooling fins, and an increasing inner diameter, and the heat sink is a taped-shaped column having a top outer diameter larger than an upper inner diameter of the sleeve; inserting the heat conductor into the sleeve from its lower side until the heat conductor enables its lateral sidewall to contact the inner periphery of the sleeve; and forcing the heat conductor into the sleeve for a predetermined depth, whereby the sleeve is forced to expand its inner periphery by its own resilience to hold the heat conductor tight. Thus, the heat sink and the heart conductor are tightly combined to enable better thermal conductivity therefor.

### BACKGROUND OF THE INVENTION

1. Field of the Invention

The present invention relates generally to thermally dissipative/conductive devices, and more particularly, to a method of combining a heat sink and a heat conductor and a combination assembly of the same.

2. Description of the Related Art

Referring to FIGS. 7-8, a conventional combination assembly 50 is composed of a heat sink 51 and a heat conductor 61. The heat sink 51 is made of aluminum, having a sleeve 52 at its center. The heat conductor 61 is columnar, having an outer diameter larger than an inner diameter of the sleeve 52. While combining the heat sink 51 and the heat conductor 61, the user has to heat the heat sink 51 to enable the sleeve 52 subject to thermal expansion to expand its inner periphery until the inner diameter of the sleeve 52 is larger than the outer diameter of the heat conductor 61 and then cool the heated heat sink 51 down. After the inner diameter of the sleeve 52 becomes smaller subject to cooling contraction, the sleeve 52 clamps the heat conductor 61 to produce the combination assembly 50.

However, the above conventional combination assembly 50 is defective to require improvement because of some drawbacks recited below. Because the heat sink 51 is made of aluminum, the temperature heating the heat sink 51 cannot be much high to prevent the heat sink 51 from softening and deformation. Further, the coefficient of expansion of the aluminum is not large, such that the heat sink 51 is limitedly deformed; thus, while the heated heat sink 51 is cooled down, the heat sink 51 fails to clamp the heat conductor 61 so well to further cause worse thermal conduction for the combination assembly 50 because the inner periphery of the heat sink 51 is not in tight contact with an outer periphery of the heat conductor 61. In addition, the sleeve 52 must have a smooth inner periphery to reduce any interference with insertion of the heat conductor 61 into the sleeve 52, requiring additional processing to increase production cost. Moreover, while manufacturing the heat conductor 61 and the heat sink 51, the tolerance must be little to, however, increase production cost because of more requirement of precision.

### SUMMARY OF THE INVENTION

The primary objective of the present invention is to provide a method of combining a heat sink and a heat conductor and a combination assembly of the same, in which the heat sink holds the heat conductor tight together to enable the combination assembly to have better thermal conductivity.

The secondary objective of the present invention is to provide a method of combining a heat sink and a heat conductor and a combination assembly of the same, which requires none of any additional processing of a smooth inner periphery of the heat sink to reduce the production cost.

The third objective of the present invention is to provide a method of combining a heat sink and a heat conductor and a combination assembly of the same, which allows more tolerance and can be done without high precision to reduce the production cost.

The foregoing objectives of the present invention are attained by the combination assembly and the method including the steps as follows. Prepare a heat sink and a heat conductor, wherein the heat sink includes a sleeve at is center, a plurality of cooling fins extending radially from an outer periphery of the sleeve, and an increasing inner diameter at an inner periphery of the sleeve from an upper section to an lower section of the sleeve, and the heat sink is a taped-shaped column having a top outer diameter larger than an upper inner diameter of the sleeve. Insert the heat conductor into the sleeve from its lower side until the heat conductor enables its lateral sidewall to contact the inner periphery of the sleeve. Force the heat conductor into the sleeve for a predetermined depth, whereby the sleeve is forced to expand its inner periphery by its own resilience to hold the heat conductor tight. Thus, the heat sink and the heart conductor are tightly combined to enable better thermal conductivity therefor.

### BRIEF DESCRIPTION OF THE DRAWINGS

FIG. 1 is an exploded view of a preferred embodiment of the present invention.

FIG. 2 is a first sectional view of the preferred embodiment of the present invention before the combination is finished.

FIG. 3 is a second sectional view of the preferred embodiment of the present invention before the combination is finished.

FIG. 4 is a third sectional view of the preferred embodiment of the present invention before the combination is finished.

FIG. 5 is a fourth sectional view of the preferred embodiment of the present invention before the combination is finished.

FIG. 6 is a schematic view of the preferred embodiment of the present invention.

FIG. 7 shows a sectional view of a conventional combination assembly of a heat sink and a heat conductor before they are combined.

FIG. 8 shows a sectional view of the conventional combination assembly

### DETAILED DESCRIPTION OF PREFERRED EMBODIMENTS

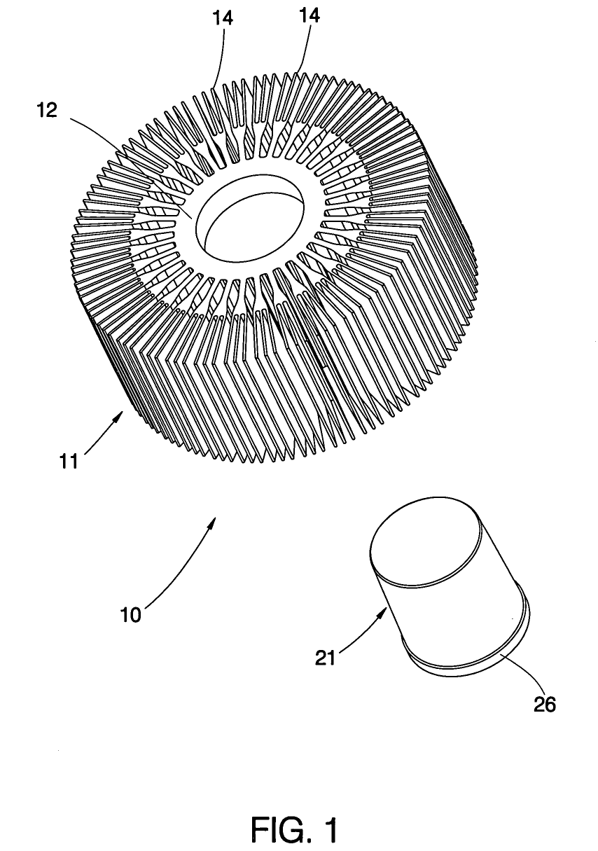

Referring to FIGS. 1-6, a method of combining a heat sink and a heat conductor and the combination assembly 10 of the same, in accordance with a preferred embodiment of the present invention, includes the following steps and the structure.

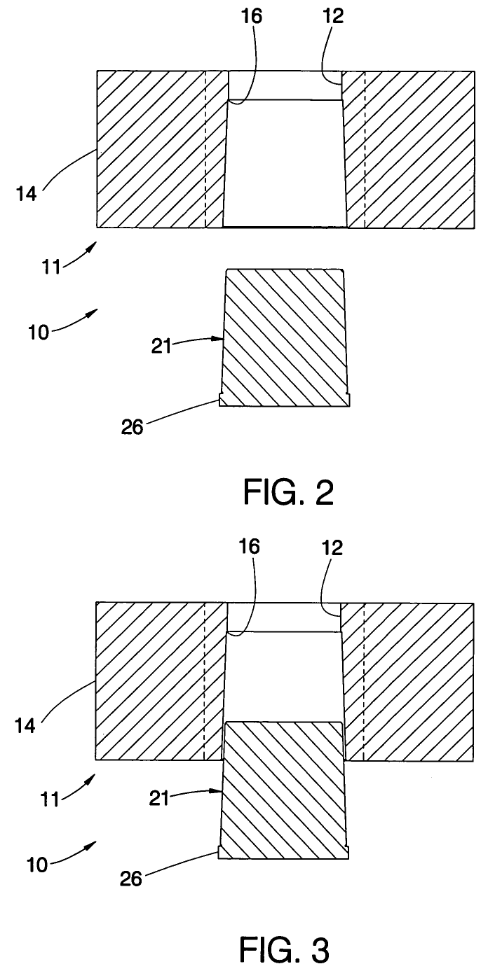

A) Prepare a heat sink 11 and a heat conductor 21, as shown in FIGS. 1 and 2. The heat sink 11 has a sleeve 12 at its center, a plurality of cooling fins 14 extending radially outwards from an outer periphery of the sleeve 12, a stepped portion 16 provided at an upper section of an inner periphery of the sleeve 12, and an annular portion 26 provided around a bottom end of the heat conductor 21. The sleeve 12 has an increasing inner diameter from its top end to its bottom end to be taper-shaped at its inner side. An upper inner diameter of the sleeve 12 is smaller than a top outer diameter of the heat conductor 21.

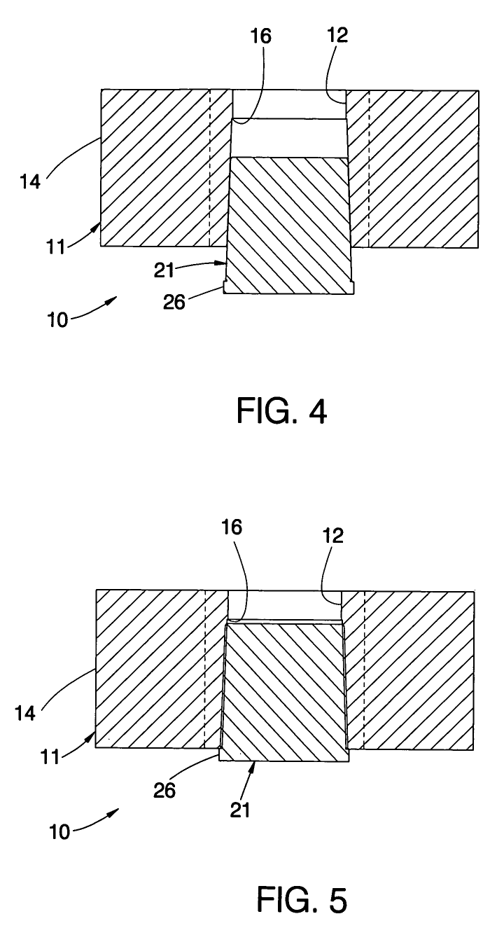

B) Insert the heat conductor 21 into the sleeve 12 from a lower side of the sleeve 12, as shown FIGS. 3 and 4, and push the heat conductor 21 until a lateral sidewall of the heat conductor 21 contacts the inner periphery of the sleeve 12.

C) Force the heat conductor 21 into the sleeve 12 until a front end of the heat conductor 21 contacts against the stepped portion 16 or until the annular portion 26 contacts against a bottom end of the sleeve 12, as shown in FIG. 5. When the annular portion 26 contacts against the bottom end of the sleeve 12, the sleeve 12 is forced to expand its inner periphery to hold the heat conductor 21 tight. A normal line provided at the inner periphery of the sleeve 12 intersects with the direction that the heat conductor 21 is pushed into the sleeve 12 for an angle θ of 60-90 degree.

As indicated above, the combination assembly 10 of the heat sink 11 and the heat conductor 21 are accomplished.

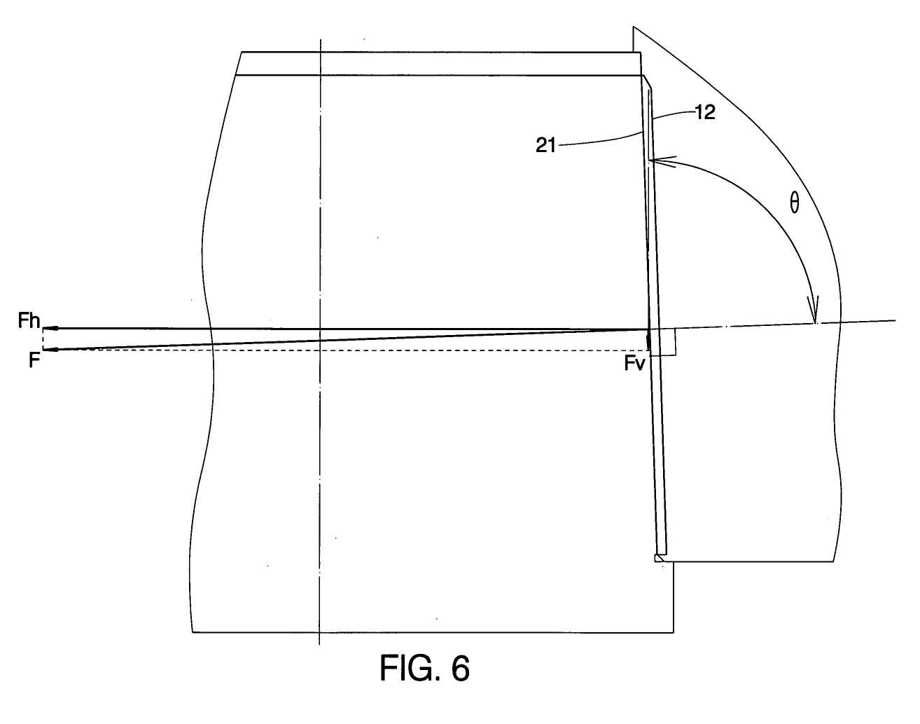

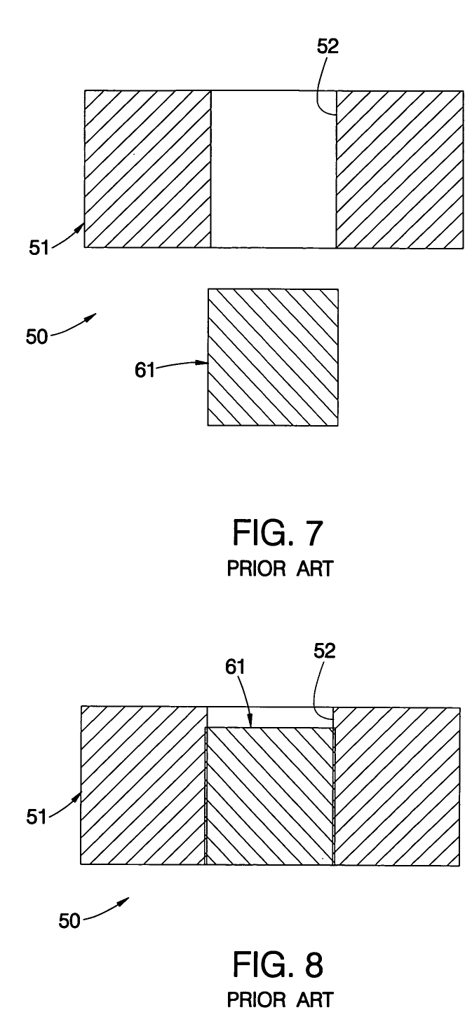

Referring to FIG. 6, the taper-shaped inner periphery of the sleeve 12 fits the taper-shaped outer periphery of the heat conductor 21, such that after the heat conductor 21 is pushed into the sleeve 12, a clamping force F generated for holding the heat conductor 21 is composed of a horizontal component Fh and a vertical component Fv. Because the horizontal component Fh is greater than the vertical component Fv, the heat conductor 21 is held tight by the horizontal component Fh rather than pushed outwards by the vertical component Fv. Thus, the heat conductor 21 will not slip off the heat sink 11.

In addition, in the above-mentioned steps, if the heat sink 11 is heated before the heat conductor 21 is pushed into the heat sink 11, the inner diameter of the sleeve 12 can be enlarged more to help push the heat conductor 21 into the heat sink 11 to facilitate the combination.

In conclusion, the present invention includes the following advantages.

1. The heat conductor can be held too tight to be disengaged from the heat sink, thereby overcoming the drawback of the prior art caused by that the heat sink subject to its insufficient coefficient of expansion fails to hold the heat conductor tight, further enabling the better thermal conductivity for the present invention.

2. Because the heat conductor contacts the heat sink by their taper-shaped periphery, the inner periphery of the heat sink is unnecessarily smooth to allow successful entry of the heat conductor into the sleeve. In other words, the sleeve requires none of any additional precise processing on the inner periphery for smoothness to reduce the production cost.

3. Because the present invention is combined by that the heat conductor is pushed into the sleeve from outside, more tolerance is allowed between the heat sink and the heat conductor. In other words, the present invention does not require little tolerance and high precision for combination to avoid high production cost incurred by requirement of the high precision.

What is claimed is:

1. A method of combining a heat sink and a heat conductor comprising steps:
(a) Preparing a heat sink and a columnar heat conductor, wherein said heat sink has a sleeve at its center and a plurality of cooling fins extending radially outwards from an outer periphery of said sleeve, said sleeve has an increasing inner diameter from its upper section to its lower section, said heat conductor has an increasing outer diameter from its top end to its bottom end, and an upper inner diameter of said sleeve is smaller than a top outer diameter of the heat conductor;
(b) Inserting said heat conductor into said sleeve from its lower side until said heat conductor enables its lateral sidewall to contact an inner periphery of said sleeve; and
(c) Forcing said heat conductor into said sleeve for a predetermined depth, whereby said sleeve is forced to expand its inner periphery to hold the heat conductor tight by its own resilience.

2. The method as defined in claim 1, wherein a normal line provided at the inner periphery of said sleeve intersects with the direction that said heat conductor is inserted into said sleeve for an angle of 60-90 degree.

3. The method as defined in claim 1, wherein said sleeve comprises a stepped portion at its inner periphery; said heat conductor enables its front end to contact against said stepped portion of said sleeve in said step (c).

4. The method as defined in claim 1, wherein said heat conductor comprises an annular portion around its bottom end, said annular portion contacting against a bottom end of said sleeve.

5. A combination assembly of a heat sink and a heat conductor, comprising:
a heat sink having a sleeve at its center and a plurality of cooling fins extending radially outwards from an outer periphery of said sleeve, said sleeve having an increasing inner diameter from its top end to its bottom end;
a columnar heat conductor tightly inserted into said sleeve, said heat conductor having an increasing outer diameter from its top end to its bottom end, an upper inner diameter of said sleeve being smaller than a top outer diameter of said heat conductor.

6. The combination assembly as defined in claim 5, wherein said sleeve comprises a stepped portion at an upper section of an inner periphery of said sleeve.

7. The combination assembly as defined in claim 5, wherein said heat conductor comprises an annular portion around its bottom end.
